(19) United States
(12) Patent Application Publication
(10) Pub. No.: US 2026/0212099 A1
(43) Pub. Date: Jul. 23, 2026

(54) CHANNEL-LESS DISTRIBUTED DESIGN-FOR-TEST ARCHITECTURE

(71) Applicant: QUALCOMM Incorporated, San Diego, CA (US)

(72) Inventors: Arvind Jain, San Diego, CA (US); Adarsh Arora, San Diego, CA (US); Pavan Kumar Patibanda, San Diego, CA (US); Madan Krishnappa, San Diego, CA (US)

(21) Appl. No.: 19/033,119

(22) Filed: Jan. 21, 2025

(51) Int. Cl. G06F 30/333; G06F 30/327

(52) U.S. Cl. CPC G06F 30/333; G06F 30/327

(57) ABSTRACT

A channel-less design-for-test (DFT) architecture implements distributed test functionality across hardware modules (HMs) of an integrated circuit. The architecture includes a center HM and peripheral HMs interconnected by a standardized bus that carries DFT data communication. Each HM incorporates DFT circuitry comprising a scan shift network (SSN) and an encoder/decoder for test (EDT) circuit to perform local test operations. The center HM includes SSN multiplexing circuitry that manages SSN connections for coordinated test operations across the HMs. This distributed architecture eliminates the need for dedicated test routing channels between modules while enabling independent DFT operations within each HM. The standardized bus interface reduces routing complexity and supports efficient test data communication between modules.

### TECHNICAL FIELD

This disclosure relates generally to design-for-test (DFT) architectures for integrated circuits, and more specifically, to a distributed, channel-less DFT architecture that localizes DFT operations within hardware modules while enabling inter-module test communication through a bus interface.

### BACKGROUND

Design-for-test (DFT) architectures are important for screening manufacturing defects in integrated circuits in complex system-on-chip (SoC) designs. The increasing sophistication of SoC designs necessitates DFT implementations that introduce additional logic overhead, which impacts area utilization and design complexity. Traditional DFT architectures rely on a top-level partition to manage test operations across different hardware modules (HMs) within the SoC. But doing so requires dedicated routing channels between the top-level partition and individual HMs to facilitate test data communication.

The evolution of physical design methods toward channel-less implementations to optimize floor planning and reduce area overhead creates implementation challenges for conventional top-level DFT partition approaches. The interdependency between top-level and hardware module center (HM center) implementations extends design cycles and complicates timing closure efforts. Routing numerous test signals through dedicated channels results in increased routing congestion and area overhead. The validation and verification of the top-level partition represents a bottleneck in the overall design flow.

Some approaches attempt to address the foregoing challenges by creating a pseudo top partition within a center tile design. However, this workaround introduces complex routing requirements between different modules, unpredictable timing closure, and inefficient physical design. Existing solutions also face difficulty in maintaining consistent operation across different design representations, e.g., from register-transfer level (RTL) to gate-level implementations. This is particularly true for managing test clock distribution and scan chain operations across multiple clock and voltage domains. Accordingly, there exists a need for improved DFT architectures that eliminate the traditional reliance on top-level partitions while maintaining robust test capabilities in modern channel-less SoC designs.

### SUMMARY

The following summarizes some aspects of the present disclosure to provide a basic understanding of the discussed technology. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later. The systems and devices of this disclosure each have several innovative aspects, no single one of which is solely responsible for the desirable attributes disclosed herein.

One innovative aspect of the subject matter described in this disclosure can be implemented in an integrated circuit device. The integrated circuit device includes a plurality of hardware modules (HMs) including a center HM, interconnected by a bus configured for design-for-test (DFT) data communication. Each HM implements DFT circuitry comprising a scan shift network (SSN) and an encoder/decoder for test (EDT) circuit to perform DFT operations. The center HM includes SSN multiplexing circuitry that manages SSN connections for the plurality of HMs.

In some examples, the SSN multiplexing circuitry coordinates operations across the HMs while each HM executes local DFT operations. The HMs may include interfaces for both register-transfer level descriptions and gate-level netlists, enabling consistent DFT operations across different design representations. The architecture supports multiple clock and voltage domains through dedicated interface modules. The center HM may include on-chip clock circuitry for distributing test clock signals.

In other examples, each HM's SSN processes local scan operations while the bus carries inter-module data. The SSN multiplexing circuitry receives, multiplexes, and transmits scan data between HMs via the bus, with HMs operating independently. The bus, which may comprise 32 bits, carries all DFT signals between modules.

Some HMs may implement channel wrapper tiles containing EDT and SSN circuits positioned within channels along with strategically placed clock circuitry and loopback routing. The architecture may include JTAG debug registers in each HM coordinated by a host circuit in the center HM, thereby enabling single JTAG interfaces. DFT controller circuits may manage local test operations through integrated JTAG and test control register implementations.

Another innovative aspect of the subject matter described in this disclosure can be implemented in a method for performing distributed design-for-test operations. The method includes providing a plurality of hardware modules (HMs) including a center HM, interconnecting these HMs with a bus for DFT data communication, and implementing DFT circuitry in each HM. The DFT circuitry in each HM includes a scan shift network (SSN) and an encoder/decoder for test (EDT) circuit, with the center HM incorporating SSN multiplexing circuitry to manage SSN connections across the HMs.

In some examples, the method includes coordinating SSN operations across the HMs while executing local DFT operations within each module. The method may involve implementing channel wrapper tiles, positioning EDT and SSN circuits within channels, and configuring loopback circuitry for internal signal routing. Some implementations incorporate JTAG debug functionality by implementing IJDR circuits in each HM and an IJDR host circuit in the center HM, enabling single JTAG interfaces. The method supports independent DFT operations in each HM while maintaining coordinated communication exclusively through the interconnecting bus.

Another innovative aspect of the subject matter described in this disclosure can be implemented in a distributed test architecture specifically focused on channel wrapper implementation. This architecture includes a channel wrapper tile containing multiple communication channels, with strategically positioned test circuitry. The tile implements an EDT circuit and SSN circuit positioned within its center region to optimize test signal distribution. On-chip clock circuitry is positioned at the input interfaces of the communication channels to manage clock signal distribution. A dedicated test communication bus couples to both the EDT and SSN circuits, thereby enabling DFT data exchange with other hardware modules while maintaining the distributed nature of the architecture.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

The integrated circuits and System on Chips (SoCs) described herein may be used for processing of various kinds of data, including audio signal processing, video processing, artificial intelligence (AI) processing, mathematical computations, database processing, image processing, and other kinds of data processing. These integrated circuits and/or SoCs can be incorporated into a wide variety of devices. By way of example, they may be incorporated into stand-alone audio devices, such as entertainment devices and personal media players, wireless communication device handsets such as mobile telephones, cellular or satellite radio telephones, personal digital assistants (PDAs), tablets, gaming devices, computing devices such as webcams, video surveillance cameras, or other devices that process data using processing circuitry (e.g., application specific integrated circuits (ASICs), digital signal processors (DSP), graphics processing unit (GPU), or central processing units (CPU)).

In some aspects, a device may include a digital signal processor or a processor (e.g., an application processor) including specific functionality for data processing. Operations on different kinds of data may be performed by different processors, or various operations may be split between the various data processing circuitry (e.g., ASICs, DSP, GPU, CPU, NPU). In some embodiments, the methods and techniques disclosed herein may be adapted for use in a neural signal processor (NSP) in which one or more parameters of data processing are controlled based on output from a machine learning (ML) model executed by the NSP.

Other aspects, features, and implementations will become apparent to those of ordinary skill in the art, upon reviewing the following description of specific, exemplary aspects in conjunction with the accompanying figures. While features may be discussed relative to certain aspects and figures below, various aspects may include one or more of the advantageous features discussed herein. In other words, while one or more aspects may be discussed as having certain advantageous features, one or more of such features may also be used in accordance with the various aspects. In similar fashion, while exemplary aspects may be discussed below as device, system, or method aspects, the exemplary aspects may be implemented in various devices, systems, and methods.

The method may be embedded in a computer-readable medium as computer program code comprising instructions that cause a processor to perform the steps of the method. In some embodiments, the processor may be part of a mobile device including a first network adaptor configured to transmit data, such as images or videos (with associated or embedded sounds) in a recording or as streaming data, over a first network connection of a plurality of network connections; and a processor coupled to the first network adaptor and the memory. The processor may cause the transmission of output image frames described herein over a wireless communications network such as a 5G NR communication network.

The foregoing has outlined, rather broadly, the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. It is intended that innovations described herein may be practiced in a wide variety of devices, chip-level components, systems, distributed arrangements, end-user devices, etc. of varying sizes, shapes, and constitution.

### DESCRIPTION OF THE FIGURES

FIG. 1 shows a block diagram of a system-on-chip (SoC) configured for performing signal processing according to one or more aspects of this disclosure.

FIG. 2 shows a flowchart illustrating a process for performing channel-less design-for-test operations in an integrated circuit device according to one or more aspects of this disclosure.

FIG. 3 shows a block diagram of an example system-on-chip apparatus implementing a distributed channel-less design-for-test architecture according to one or more aspects of this disclosure.

FIG. 4 shows a flowchart illustrating a process for implementing test operations in a channel wrapper tile according to one or more aspects of this disclosure.

FIG. 5 shows a block diagram of an example system-on-chip apparatus implementing a distributed test architecture through channel wrapper tiles according to one or more aspects of this disclosure.

FIG. 6 shows an example implementation of a channel wrapper tile 600 incorporating embedded design-for-test (DFT) components for narrow channel architectures according to aspects described herein

Like reference numbers and designations in the various drawings indicate like elements.

### DETAILED DESCRIPTION

The present disclosure provides systems, apparatus, methods, and computer-readable media that support improved integrated circuit operation, including techniques for implementing a distributed, channel-less design-for-test (DFT) architecture. Disclosed architectures localize DFT functionality within hardware modules while enabling coordinated test operations through a standardized bus interface, which eliminates dependencies on top-level test partitions and dedicated routing channels. The techniques include strategic positioning of test components within hardware modules, centralized management of scan operations through multiplexing circuitry in a center hardware module, as well as efficient test data communication across modules through a unified bus structure.

In view of the foregoing, a distributed design-for-test (DFT) architecture can be implemented across multiple hardware modules (HMs) in an integrated circuit to facilitate manufacturing test operations. According to some implementations, the architecture can distribute test functionality across HMs while enabling coordinated test operations through standardized interfaces and communication protocols. Each HM can include dedicated DFT circuitry comprising scan shift network (SSN) components and encoder/decoder for test (EDT) circuits configured to perform local test operations. The architecture can include a center HM incorporating SSN multiplexing circuitry that may coordinate scan operations across the distributed modules. A standardized bus interface can carry test data communication between modules, potentially eliminating traditional routing channel requirements.

Some implementations may incorporate channel wrapper tiles configured to handle test operations for specific circuit regions. The channel wrapper tiles can include strategically positioned test components to facilitate signal routing efficiency. According to certain aspects, on-chip clock (OCC) circuitry can be positioned at channel interfaces to manage test clock distribution while maintaining synchronization across different clock and voltage domains. The architecture can also support debug capabilities through integrated Joint Test Action Group (JTAG) debug registers distributed across the HMs. In some implementations, the debug registers may be coordinated by host circuitry implemented within the center HM, enabling unified test control across the distributed architecture.

Channel wrapper tiles according to various aspects can implement EDT and SSN circuits positioned to optimize signal routing while minimizing congestion. The OCC circuitry positioned at channel interfaces can facilitate both test clock generation and distribution across multiple clock domains. Some implementations can include loopback circuitry configured to route test signals within individual channel wrapper tiles, potentially enabling localized test pattern application and response capture.

Test data communication between modules can be managed through a standardized bus interface, which in some implementations may comprise a 32-bit structure. This bus interface can be configured to carry all inter-module DFT signals, including scan data, control signals, and test responses. The architecture may support direct communication between individual HMs and the center HM without requiring intermediate routing or buffering stages, reducing overall routing complexity and improving signal integrity.

According to certain implementations, the disclosed architectures can support both register-transfer level (RTL) and gate-level netlist representations through consistent interface definitions. This consistency can be maintained through dedicated input/output ports and interface circuits configured to handle multiple design abstraction levels. The architecture may include DFT controller circuits in each HM configured to manage local test operations while supporting global coordination through the center HM. Some aspects of the architecture can incorporate Test Access Port (TAP) and Test Control Register (TCR) controls implemented through integrated JTAG debug registers and control registers.

Disclosed architectures can also support scan dump operations and test data collection through dedicated logic integrated within the distributed DFT framework. Some implementations may include enhanced debug capabilities through distributed JTAG interfaces that support both standard test operations and advanced debug features. The ability to perform independent test operations within each HM while maintaining coordinated control through the center HM can enable efficient parallel test execution and reduced test time.

In certain implementations, disclosed architectures can incorporate enhanced clock distribution schemes that support both functional and test modes through unified clock generation and control circuits. The OCC circuitry can be configured to manage multiple clock domains while maintaining synchronization during test operations. Some aspects may include specialized scan chain configurations that optimize test coverage while minimizing routing overhead.

Particular implementations of the subject matter described in this disclosure may be implemented to realize one or more of the following potential advantages or benefits. In some aspects, the present disclosure provides techniques for enhancing design-for-test implementations while supporting efficient physical design in modern integrated circuits. The distributed DFT architecture can significantly reduce routing congestion by eliminating approximately thousands of dedicated routes between padbanks, channel tiles, and the center tile. This reduction in routing requirements may enable more efficient floor planning and improved area utilization.

Implementation cycles can benefit from decreased module interdependency, as each hardware module maintains autonomous test operations while coordinating through the standardized bus interface. The elimination of interdependency between top-level and hardware module center implementations can reduce design cycle time from weeks to days. The architecture supports predictable timing closure by eliminating long scan paths that traditionally required extensive pipeline stages for signal preservation. Also, physical design planning can be simplified through the standardized bus-based communication structure. The removal of pre-defined feedthrough requirements associated with traditional test partitions reduces physical design complexity and enables more predictable routing solutions. By eliminating the pseudo top partition in center tile designs, the architecture can avoid the complex routing requirements and unpredictable timing closure challenges typically associated with such implementations.

The distributed architecture enables independent module implementation and validation, potentially accelerating development timelines. Test pattern generation and application can proceed independently for each hardware module, reducing overall test development time. The localized DFT control structures, implemented through dedicated controller circuits and embedded JTAG debug registers, can save hundreds of routes per hardware module while maintaining comprehensive test coverage.

Some implementations support efficient test signal distribution through strategic component placement within channel wrapper tiles. The positioning of EDT and SSN circuits in channel centers, combined with optimally placed OCC circuitry at channel interfaces, creates an efficient test infrastructure that minimizes routing overhead. The capability for parallel test execution across independently operating modules reduces overall test time while maintaining test coverage.

The architecture supports consistent operation across different design representations through standardized interfaces, simplifying verification throughout development stages. The unified approach to handling both RTL and gate-level implementations eliminates potential discrepancies during design transitions. The integration of debug capabilities through distributed JTAG interfaces provides enhanced visibility while maintaining the localized control structure. Further, by implementing channel-less DFT architecture with localized control structures, physical design teams can pre-plan feedthrough requirements more effectively, potentially saving approximately one week of physical design effort. The reduced routing complexity and elimination of top-level partition dependencies contribute to more predictable implementation flows and improved design closure characteristics.

The detailed description set forth below, in connection with the appended drawings to which the text references, is intended as a description of various embodiments and is not intended to limit the scope of the disclosure. Rather, the detailed description includes specific details for the purpose of providing a thorough understanding of the subject matter of this disclosure. It will be apparent to those skilled in the art that these specific details are not required in every case and that, in some instances, well-known structures and components are shown in block diagram form for clarity of presentation.

In the description of embodiments herein, numerous specific details are set forth, such as examples of specific components, circuits, and processes to provide a thorough understanding of the present disclosure. The term “coupled” as used herein means connected directly to or connected through one or more intervening components or circuits. Also, in the following description and for purposes of explanation, specific nomenclature is set forth to provide a thorough understanding of the present disclosure. However, it will be apparent to one skilled in the art that these specific details may not be required to practice the teachings disclosed herein. In other instances, well known circuits and devices are shown in block diagram form to avoid obscuring teachings of the present disclosure.

Some portions of the detailed descriptions which follow are presented in terms of procedures, logic blocks, processing, and other symbolic representations of operations on data bits within a computer memory. In the present disclosure, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system.

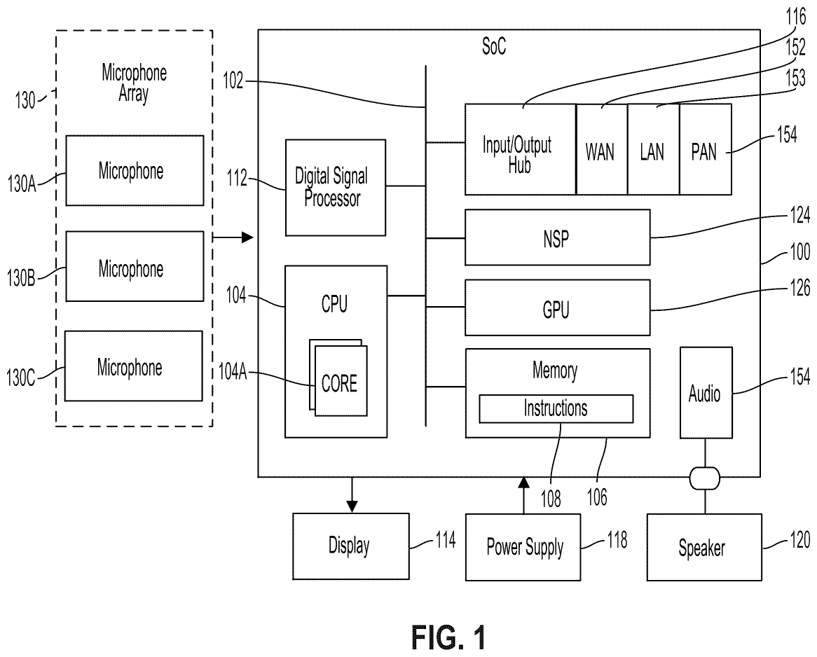

FIG. 1 shows a block diagram of a system-on-chip (SoC) configured for performing signal processing according to one or more aspects of this disclosure. The SoC 100 may include several components coupled together through a bus 102, which may be a network-on-a-chip (NoC) or a plurality of NOCs interconnecting various components. For example, although FIG. 1 illustrates several components coupled to the bus 102, the several components may be coupled to different busses with additional busses connecting the different busses to provide a path for communication between the components.

One example component in the SoC 100 is a digital signal processor 112 for signal processing. The DSP 112 may process audio signals received from microphones 130A, 130B, and 130C of microphone array 130. The DSP 112 may include hardware customized for performing a limited set of operations on specific kinds of data. For example, a DSP may include transistors coupled together to perform operations on streaming data and use memory architectures and/or access techniques to fetch multiple data or instructions concurrently. Such configurations may allow the DSP 112 to operate on real-time data, such as video data, audio data, or modem data, in a power-efficient manner.

The SoC 100 also includes a central processing unit (CPU) 104 and a memory 106 storing instructions 108 (e.g., a memory storing processor-readable code or a non-transitory computer-readable medium storing instructions) that may be executed by a processor of the SoC 100. The CPU 104 may be a single central processing unit (CPU) or a CPU cluster comprising two or more cores such as core 104A. The CPU 104 may include hardware capable of performing generic operations on many kinds of data, such as hardware capable of executing instructions from the Advanced RISC Machines (ARM®) instruction set, such as ARMv8 and ARMv9. For example, a CPU 104 may include transistors coupled together to perform operations for supporting executing an operating system and user applications (e.g., a camera application, a multimedia application, a gaming application, a productivity application, a messaging application, a videocall application, an audio recording application, a video recording application). The CPU 104 may execute instructions 108 retrieved from the memory 106. In some embodiments, the CPU 104 executing an operating system may coordinate execution of instructions by various components within the SoC 100. For example, the CPU 104 may retrieve instructions 108 from memory 106 and execute the instructions on the DSP 112.

The SoC 100 may further include a neural signal processor (NSP) 124 for executing machine learning (ML) models relating to multimedia applications. The NSP 124 may include hardware configured to perform and accelerate convolution operations involved in executing machine learning algorithms. For example, the NSP 124 may improve performance when executing predictive models such as artificial neural networks (ANNs) (including multilayer feedforward neural networks (MLFFNN), the recurrent neural networks (RNN), and/or the radial basis functions (RBF)). The ANN executed by the NSP 124 may access predefined training weights stored in the memory 106 for performing operations on user data.

The SoC 100 may be coupled to a display 114 for interacting with a user. The SoC 100 may also include a graphics processing unit (GPU) 126 for rendering images on the display 114. In some embodiments, the CPU 104 may perform rendering to the display 114 without a GPU 126. In some embodiments, the GPU 126 may be configured to execute instructions for performing operations unrelated to rendering images, such as for processing large volumes of datasets in parallel.

The SoC 100 may include an integrated circuit, such as included in one of the processors DSP 112, CPU 104, NSP 124, GPU 126, to implement a channel-less design-for-test (DFT) architecture. The DFT architecture includes multiple hardware modules (HMs) distributed across the integrated circuit, with one module designated as a center HM. Each HM incorporates dedicated DFT circuitry comprising a scan shift network (SSN) and an encoder/decoder for test (EDT) circuit to enable localized test operations. The HMs communicate through a standardized bus interface, eliminating traditional dedicated test routing channels. The center HM includes specialized SSN multiplexing circuitry that coordinates test operations across the distributed modules while maintaining independent test execution capabilities within each module. This distributed architecture supports efficient manufacturing test operations by integrating test components directly within the hardware modules and managing test data communication through the existing bus infrastructure. The implementation may include channel wrapper tiles with strategically positioned test circuits, on-chip clock distribution networks, and debug interfaces that enable comprehensive test coverage while minimizing routing overhead and implementation complexity. This approach aligns with the SoC's modular architecture while providing efficient test capabilities for verifying manufacturing quality and functional correctness of the integrated components.

Processing algorithms, techniques, and methods may be executed by at least one processor of the SoC 100, which may include execution by all steps on one of the processors (e.g., DSP 112, CPU 104, NSP 124, GPU 126) or may include execution of steps across a combination of one or more of the processors (e.g., DSP 112, CPU 104, NSP 124, GPU 126). The distributed design-for-test (DFT) architecture involves hardware-based test operations rather than software processing, with test functionality integrated directly into the hardware modules of the SoC 100. In some embodiments, at least one of the DSP 112 or the CPU 104 executes instructions to coordinate test operations across the distributed hardware modules through configuration of the DFT circuitry and management of test data communication. For example, the CPU 104 may configure the SSN multiplexing circuitry in the center hardware module to coordinate scan operations across multiple modules while maintaining independent test execution capabilities. The DFT operations enable comprehensive testing of the integrated components through scan chain operations, clock distribution, and debug interfaces implemented directly in hardware.

The CPU 104 may initialize test configurations and monitor test results while the actual test operations execute through dedicated hardware circuitry distributed across the modules. This hybrid approach leverages the CPU's control capabilities for test management while utilizing dedicated DFT components for efficient test execution. The hardware modules communicate test data through a standardized bus interface, eliminating traditional dedicated routing channels while maintaining comprehensive test coverage. Configuration of the test architecture may respond to system requirements or test modes, with the CPU 104 coordinating the overall test strategy while individual hardware modules execute their respective test operations independently.

Input/output components may be coupled to the SoC 100 through an input/output (I/O) hub 116. An example of a hub 116 is an interconnect to a peripheral component interconnect express (PCIe) bus. Example components coupled to hub 116 may be components used for interacting with a user, such as a touch screen interface and/or physical buttons. Some components coupled to hub 116 may also include network interfaces for communicating with other devices, including a wide area network (WAN) adaptor (e.g., WAN adaptor 152), a local area network (LAN) adaptor (e.g., LAN adaptor 153), and/or a personal area network (PAN) adaptor (e.g., PAN adaptor 154). A WAN adaptor 152 may be a 4G LTE or a 5G NR wireless network adaptor. A LAN adaptor 153 may be an IEEE 802.11 WiFi wireless network adapter. A PAN adaptor 154 may be a Bluetooth wireless network adaptor. Each of the WAN adaptor 152, LAN adaptor 153, and/or PAN adaptor 154 may be coupled to an antenna that may be shared by each of the adaptors 152, 153, and 154, or coupled to multiple antennas configured for primary and diversity reception and/or configured for receiving specific frequency bands. In some embodiments, the WAN adaptor 152, LAN adaptor 153, and/or PAN adaptor 154 may share circuitry, such as portions of a radio frequency front end (RFFE).

Audio circuitry 154 may be integrated in SoC 100 as dedicated circuitry for coupling the SoC 100 to a speaker 120 external to the SoC 100, which may be a transducer such as a speaker (either internal to or external to a device incorporating the SoC 100) or headphones. The audio circuitry 154 may include coder/decoder (CODEC) functionality for processing digital audio signals. The audio circuitry 154 may further include one or more amplifiers (e.g., a class-D amplifier) for driving a transducer coupled to the SoC 100 for outputting sounds generated during execution of applications by the SoC 100. Functionality related to audio signals described herein may be performed by a combination of the audio circuitry 154 and/or other processors of the SoC (e.g., CPU 104, DSP 112, GPU 126, NSP 124).

The SoC 100 may couple to external devices outside the package of the SoC 100. For example, the SoC 100 may be coupled to a power supply 118, such as a battery or an adaptor to couple the SoC 100 to an energy source. The signal processing described herein may be adapted to and achieve power efficiency to support operation of the SoC 100 from a limited-capacity power supply 118 such as a battery. For example, operations may be performed on a portion of the SoC 100 configured for performing the operation at a lowest power consumption. As another example, operations themselves are performed in a manner that reduces an amount of computations to perform the operation, such that the algorithm is optimized for extending the operational time of a device while powered by a limited-capacity power supply 118. In some embodiments, the operations described herein may be configured based on a type of power supply 118 providing energy to the SoC 100. For example, a first set of operations may be executed to perform a function when the power supply 118 is a wall adaptor. As another example, a second set of operations may be executed to perform a function when the power supply 118 is a battery.

The SoC 100 may also include or be coupled to additional features or components that are not shown in FIG. 1. Although components are shown integrated as a single SoC 100, which may include all components built on a single semiconductor die with a common semiconductor substrate, other arrangements of the illustrated blocks different number of dies, substrates, and/or packages may be arranged to accomplish the same functionality described in this disclosure.

The memory 106 may include a non-transient or non-transitory computer readable medium storing computer-executable instructions as instructions 108 to perform all or a portion of one or more operations described in this disclosure. The instructions 108 may include a multimedia application (or other suitable application such as a messaging application) to be executed by the SoC 100 that records, processes, or outputs audio signals. The instructions 108 may also include other applications or programs executed by the SoC 100, such as an operating system and applications other than for multimedia processing.

In addition to instructions 108, the memory 106 may also store audio data. The SoC 100 may be coupled to an external memory and configured to access the memory for writing output audio files for later playback or long-term storage. For example, the SoC 100 may be coupled to a flash storage device comprising NAND memory for storing video files (e.g., MP4-container formatted files) including audio tracks and/or storing audio recordings (e.g., MPEG-1 Layer 3 files, also referred to as MP3 files). Portions of the video or audio files may be transferred to memory 106 for processing by the SoC 100, with the resulting signals after processing encoded as video or audio files in the memory 106 for transfer to the long-term storage.

While the SoC 100 is referred to in the examples herein for performing aspects of the present disclosure, some device components may not be shown in FIG. 1 to prevent obscuring aspects of the present disclosure. Additionally, other components, numbers of components, or combinations of components may be included in a suitable device for performing aspects of the present disclosure. As such, the present disclosure is not limited to a specific device or configuration of components, including the device 100.

The SoC of FIG. 1 implements a distributed design-for-test architecture that improves manufacturing test efficiency and hardware validation capabilities through strategically positioned test components across hardware modules. This architecture enhances test coverage and reduces implementation complexity by eliminating dedicated test routing channels in favor of a standardized bus interface for test data communication. The distributed approach enables independent test execution within individual hardware modules while maintaining coordinated test operations through centralized multiplexing circuitry. This results in reduced routing congestion, simplified physical design, and improved test pattern application efficiency. The integration of test functionality directly within hardware modules, combined with localized clock distribution and debug interfaces, provides test coverage while minimizing overhead.

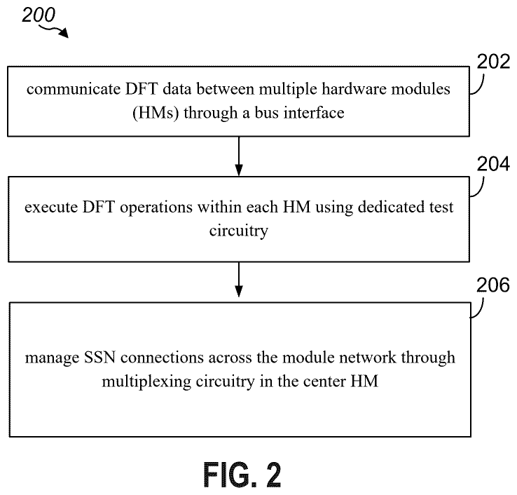

FIG. 2 shows a flowchart illustrating a process 200 performable by an integrated circuit device that supports channel-less design-for-test (DFT) operations. A semiconductor device or its components may implement the operations of process 200. For example, an integrated circuit device such as the SoC 100 described with reference to FIG. 1 performs the process while configured to support distributed test operations.

At step 202, the device communicates DFT data between multiple hardware modules (HMs) through a bus interface. The bus interface eliminates dedicated routing channels by providing a shared communication path for test-related data exchange. In some implementations, a 32-bit bus structure supports bandwidth requirements for test operations while maintaining routing efficiency. All inter-module DFT signals travel through this shared bus infrastructure, thereby removing dependencies on dedicated routing paths between modules.

At step 204, the device executes DFT operations within each HM using dedicated test circuitry. In some implementations, scan shift network (SSN) components and encoder/decoder for test (EDT) circuits distributed across the modules can perform these operations. Each HM independently conducts local test operations according to specific test requirements. The modular implementation allows simultaneous test execution across multiple HMs, reducing overall test time. Different operational modes accommodate various test scenarios through register-transfer level (RTL) and gate-level netlist interfaces, while modules manage transitions between clock domains and voltage interfaces.

At step 206, the device manages SSN connections across the module network through multiplexing circuitry in the center HM. The multiplexing circuitry coordinates operations while maintaining independence between modules. Through the bus infrastructure, the center HM receives scan data from individual HMs, performs multiplexing operations on the received data, and transmits processed data back to the modules. This approach enables efficient test data handling within the distributed architecture.

For implementations incorporating channel wrapper tiles, additional steps configure embedded DFT components. EDT and SSN circuits positioned within specific channels process test data. On-chip clock (OCC) circuitry placed at signal entry points manages timing coordination. Loopback circuitry routes test signals within the wrapper tiles to optimize pattern application and response capture.

The process includes steps for controlling DFT operations through integrated Joint Test Action Group (JTAG) interfaces. JTAG debug registers in individual HMs coordinate with a dedicated host circuit in the center HM. This configuration establishes a single JTAG interface for each HM while preserving independent module operation. The JTAG host circuit enables the interfaces and manages test control across the modules.

Throughout execution, the process 200 can maintain module independence while ensuring coordinated control. The bus infrastructure facilitates communication between independently operating modules as needed. The center HM's multiplexing circuitry manages data flow between modules without imposing operational dependencies. This distributed approach reduces routing congestion and simplifies physical design without affecting test coverage.

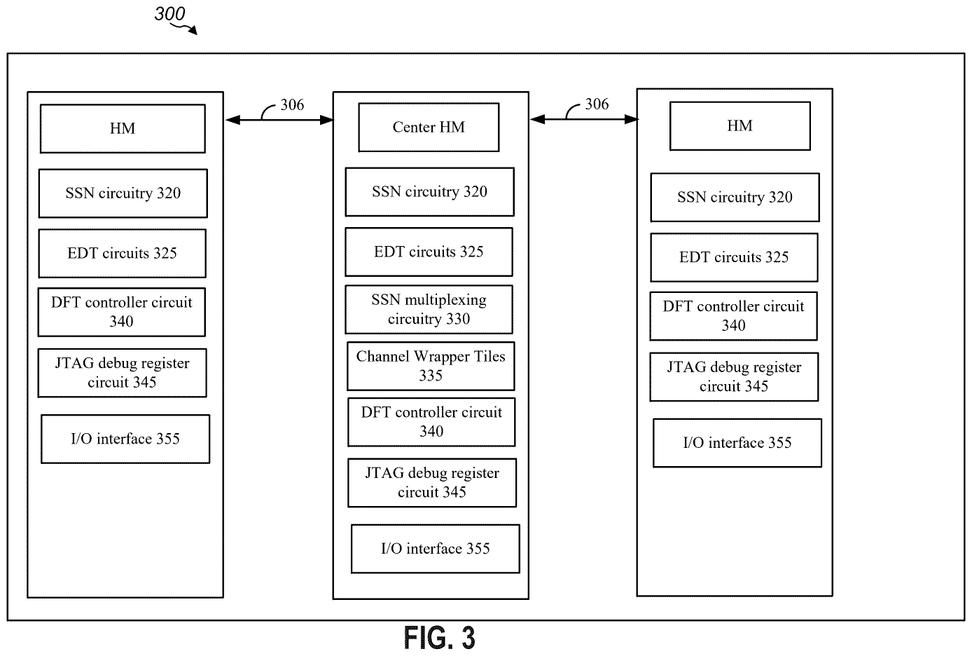

FIG. 3 is a block diagram of an example system-on-chip (SoC) apparatus 300 that supports channel-less design-for-test operations according to aspects described herein. Apparatus 300 may be an example of aspects of the SoC described in the previous figures. Apparatus 300 may include various components described herein, and one or more components of apparatus 300 may include at least one processor, which may be coupled with at least one memory, to support or enable the described techniques. Each of these components may be in communication with one another via one or more buses.

Apparatus 300 includes multiple hardware modules (HMs) interconnected through a bus interface, with one HM designated as a center HM. Each HM contains dedicated design-for-test (DFT) circuitry configured to execute local test operations while maintaining communication with other modules through the bus infrastructure. The modular architecture enables independent test execution while preserving control through centralized management functions. This approach minimizes routing congestion and simplifies physical design implementation across the system.

Each HM includes scan shift network (SSN) circuitry 320 and encoder/decoder for test (EDT) circuits 325 for processing test patterns and managing scan operations within their respective modules. The center HM additionally incorporates SSN multiplexing circuitry 330 that coordinates test operations across the distributed architecture while preserving module independence. SSN multiplexing circuitry 330 is coupled to bus interface 306, which carries all inter-module DFT signals. Through this interface, test data flows between modules according to standardized protocols that support various operational modes. The bus structure may implement a 32-bit width to provide sufficient bandwidth while maintaining routing efficiency. Some implementations incorporate pipelining mechanisms to ensure reliable data transfer across longer routing distances.

Apparatus 300 may include channel wrapper tiles 335 incorporating specialized test components positioned for optimal signal routing. The tiles 335 can themselves contain EDT and SSN circuits with on-chip clock (OCC) circuitry placed at channel input interfaces. The channel wrapper tiles 335 can support multiple communication channels through strategically positioned test components that minimize routing complexity while enabling efficient pattern application and response capture. Loopback circuitry within the tiles provides flexible signal routing options for different test scenarios. Test clock distribution networks (not illustrated) extend from the interface points to maintain synchronized operation across channels.

Apparatus 300 may include JTAG debug register circuits 345 distributed across the HMs, with, in some implementations, a host circuit located in the center HM. This circuitry enables unified test control through single JTAG interfaces while maintaining independent module operation. Input/output interfaces 355 handle transitions between different clock and voltage domains across the hardware modules. These interfaces support multiple operating modes to accommodate various test requirements and system configurations.

Apparatus 300 may also include DFT controller circuits 340 integrated within each HM to manage local test operations. These controllers coordinate with the JTAG debug registers 345 and test control registers to provide test coverage while minimizing external dependencies. The controllers 340 handle scan dump operations, clock control, and test mode selection based on specific test requirements. Certain implementations may incorporate built-in self-test capabilities and fault diagnosis features through dedicated observation points within the test infrastructure.

Apparatus 300 can operate across different design representations through consistent interface definitions that support both register-transfer level (RTL) and gate-level netlist implementations. Dedicated input/output ports coupled to appropriate interface circuits enable seamless transition between abstraction levels without compromising test functionality. The architecture accommodates various clock domains and voltage interfaces through modules that manage signal transitions across domain boundaries. Implementation flexibility extends to handling different channel widths and test requirements through adaptable component placement and configurable routing resources.

As mentioned, the distributed test architecture implemented by apparatus 300 supports efficient manufacturing test operations while minimizing implementation complexity. Test pattern generation and application proceed independently for each hardware module, reducing overall test development time. The modular approach enables parallel test execution across multiple modules while maintaining coordinated control through the center HM. Further, built-in debug capabilities support post-silicon validation efforts through integrated observation and control points throughout the test infrastructure.

Various components of apparatus 300 provide means for performing method 200 described with respect to FIG. 2. For example, means for communicating DFT data may include bus interface 306 and SSN multiplexing circuitry 330. Means for executing DFT operations may include SSN circuitry 320 and EDT circuits 325. Means for managing SSN connections may include the SSN multiplexing circuitry 330 in conjunction with DFT controller circuits 340. Additional components provide support for specialized test functions, debug operations, and system integration requirements as described throughout this disclosure.

The operations described with reference to blocks of FIG. 3 may be performed on a digital signal processor (DSP), such as DSP 112 of the SoC 100 illustrated in FIG. 1. However, the operations may alternatively be performed by one or more of the processors of FIG. 1, including one or more of the CPU 104, the DSP 112, the GPU 126, or the NSP 124. For example, the CPU 104 may record audio signals from the microphone array 130 to memory 106 as part of the operations of block 302. The DSP 112 may then perform the operations of blocks 304 and 306 on the audio signals stored in memory 106, after which output signals determined by the DSP 112 may be stored in memory 106, output to audio circuitry 154 for reproduction, and/or transmitted to another device through one or more of the WAN 152, LAN 153, and/or PAN 154. In another example, the processor performing the operations of blocks 302, 304, and/or 306 may be dedicated logic circuitry for performing certain operations.

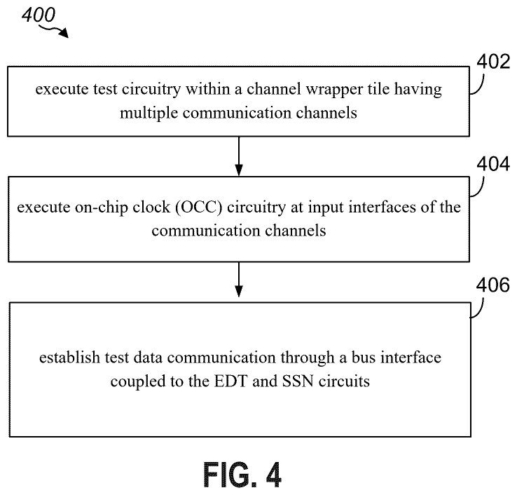

FIG. 4 shows a flowchart illustrating a process 400 performable by a channel wrapper tile implementing a distributed test architecture. A semiconductor device containing one or more channel wrapper tiles executes the operations of process 400. For instance, an integrated circuit device incorporating channel wrapper tiles as described with reference to FIG. 1 performs these operations. The process enables efficient test operations through strategic placement of test components and optimized signal routing within the channel wrapper tile architecture.

At step 402, the device executes test circuitry within a channel wrapper tile having multiple communication channels. An encoder/decoder for test (EDT) circuit and scan shift network (SSN) circuit are placed in a center region of the channel wrapper tile to optimize signal distribution. The central positioning reduces routing complexity while enabling efficient access to all channels within the tile. This arrangement minimizes signal propagation delays and supports parallel test operations across multiple channels. The EDT circuit processes incoming and outgoing test patterns, while the SSN circuit manages scan chain operations throughout the tile structure. Some implementations subdivide the center region to accommodate additional test components or specialized routing requirements based on specific channel configurations.

At step 404, the device executes on-chip clock (OCC) circuitry at input interfaces of the communication channels. The OCC circuitry generates and manages test clock signals entering the channels. Strategic placement at channel interfaces allows synchronized clock distribution while minimizing signal skew between channels. The OCC circuitry supports multiple clock domains through unified clock generation and control circuits. Clock distribution networks extend from the interface points to individual test components within each channel, maintaining signal integrity throughout the tile. Interface circuits near the OCC circuitry handle clock domain crossings and manage synchronization between channels operating at different frequencies. The foregoing arrangement accounts for physical design constraints while ensuring reliable clock delivery to all test components.

At step 406, the device establishes test data communication through a bus interface coupled to the EDT and SSN circuits. The bus carries design-for-test (DFT) data between the channel wrapper tile and other hardware modules in the system. Through this interface, the EDT circuit encodes and decodes test patterns while the SSN circuit manages scan operations within the tile.

Additional configurations of process 400 can incorporate specialized routing schemes. For example, loopback circuitry positioned within the channel wrapper tile enables internal signal routing between channels. The device may implement scan chain configurations that balance test coverage requirements with routing overhead. Some implementations support scan dump operations through dedicated logic integrated within the distributed test framework. These routing schemes facilitate efficient test pattern application and response capture while minimizing the impact on channel resources. Signal paths between test components follow optimized routes that account for physical design constraints and timing requirements. The loopback structures provide flexibility in test pattern distribution, allowing reuse of test resources across multiple channels when possible.

The process 400 accommodates varying channel widths through adaptive test circuitry placement. For narrow channels, the EDT and SSN circuits occupy minimal area while maintaining necessary test functionality. Wider channels may incorporate additional test components without impacting the overall tile architecture. The modular implementation allows configuration of channel resources based on specific test requirements. Implementation options include subdividing test circuits across multiple channels, sharing test resources between adjacent channels, or dedicating independent test components to individual channels based on bandwidth requirements. Interface circuits manage signal transitions between channels of different widths, ensuring consistent test operations regardless of channel dimensions.

Process 400 supports integration with broader test frameworks through coordinated operation with system-level test management. The channel wrapper tile coordinates operations with a center hardware module that manages system-level test functions while maintaining local control over channel-specific test operations. Interface circuits handle transitions between different clock and voltage domains across hardware modules, enabling seamless integration with the surrounding test infrastructure. Further, the distributed architecture enables parallel test execution while maintaining signal integrity through proper component placement. Test scheduling algorithms optimize resource utilization across multiple channel wrapper tiles operating simultaneously. And built-in debug capabilities support test pattern validation and fault diagnosis through dedicated observation points within the channel structure. The modular implementation simplifies verification efforts by allowing independent testing of channel-level functions before system integration.

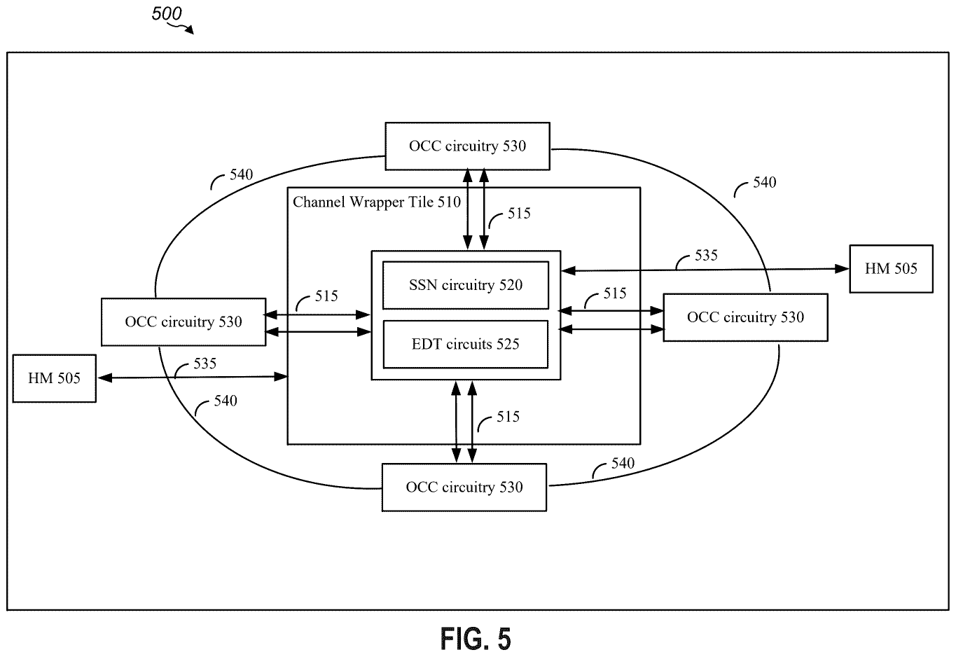

FIG. 5 is a block diagram of an example system-on-chip (SoC) apparatus 500 that implements a distributed test architecture through channel wrapper tiles according to aspects described herein. Apparatus 500 may be an example of aspects of the SoC described in the previous figures. Apparatus 500 may include various components described herein, and one or more components may include at least one processor coupled with memory to support the described techniques. Each component may communicate with others via one or more buses.

Apparatus 500 includes a channel wrapper tile 510 containing multiple communication channels 515 configured for design-for-test operations. The channels 515 provide dedicated pathways for test data while maintaining signal integrity through strategic component placement. This architecture enables efficient test pattern distribution while minimizing routing overhead through optimized placement of test circuitry within the channel structure. The channel wrapper tile 510 can incorporate encoder/decoder for test (EDT) circuitry 520 and scan shift network (SSN) circuitry 525 positioned within its center region. These centrally located components process test patterns and manage scan operations across the communication channels. EDT circuitry 520 handles encoding and decoding of test data, while SSN circuitry 525 coordinates scan chain operations throughout the tile structure. The central positioning reduces routing complexity while enabling efficient access to all channels. Implementation options include subdividing test circuits across multiple channels or sharing test resources between adjacent channels based on bandwidth requirements.

Apparatus 500 includes on-chip clock (OCC) circuitry 530 placed at input interfaces of the communication channels 515, where the placement enables synchronized clock distribution while minimizing signal skew between channels. Clock networks extend from these interface points to individual test components within each channel, maintaining timing relationships across the tile structure. The OCC circuitry supports multiple clock domains through unified generation and control circuits, with interface components managing clock domain crossings between channels operating at different frequencies.

A test communication bus 535 couples the EDT and SSN circuits to external hardware modules 505, enabling coordinated test operations across the broader system. This bus carries design-for-test (DFT) data between the channel wrapper tile and other system components according to standardized protocols. The bus interface supports various data transfer modes while maintaining signal integrity through proper termination and buffering at tile boundaries.

Apparatus 500 may include loopback circuitry 540 configured within the channel structure. This circuitry enables internal signal routing between channels and supports efficient test pattern application through local feedback paths. The loopback structures provide flexibility in test resource utilization by allowing test pattern sharing across multiple channels when possible. Implementation options include dedicated loopback paths for specific test modes or configurable routing resources that adapt to different test scenarios.

Various implementations of apparatus 500 support different channel widths through adaptive placement of test components. Narrow channels maintain essential test functionality through compact circuit arrangements, while wider channels may incorporate additional test resources without disrupting the overall architecture. Interface circuits manage signal transitions between channels of varying widths, ensuring consistent operation across the tile structure. The modular design enables efficient resource allocation based on specific channel requirements and system constraints.

The distributed architecture of apparatus 500 coordinates with system-level test management while maintaining local control over channel operations. Built-in debug capabilities support test validation through dedicated observation points within the channel structure. The channel wrapper tile may interact with center hardware modules that manage system-wide test functions, enabling comprehensive coverage while preserving the benefits of distributed control.

Various components of apparatus 500 may provide means for implementing distributed test functionality. For example, means for processing test patterns may include EDT circuitry 520 and SSN circuitry 525. Means for managing clock distribution may include OCC circuitry 530. Means for communicating test data may include test communication bus 535 and associated interface circuits. Additional components provide specialized functions supporting test operation, debug capabilities, and system integration as described throughout this disclosure.

The operations described with reference to blocks of FIG. 5 may be performed on a digital signal processor (DSP), such as DSP 112 of the SoC 100 illustrated in FIG. 1. However, the operations may alternatively be performed by one or more of the processors of FIG. 1, including one or more of the CPU 104, the DSP 112, the GPU 126, or the NSP 124. For example, the CPU 104 may record audio signals from the microphone array 130 to memory 106 as part of the operations of block 302. The DSP 112 may then perform the operations of blocks 304 and 306 on the audio signals stored in memory 106, after which output signals determined by the DSP 112 may be stored in memory 106, output to audio circuitry 154 for reproduction, and/or transmitted to another device through one or more of the WAN 152, LAN 153, and/or PAN 154. In another example, the processor performing the operations of blocks 302, 304, and/or 306 may be dedicated logic circuitry for performing certain operations.

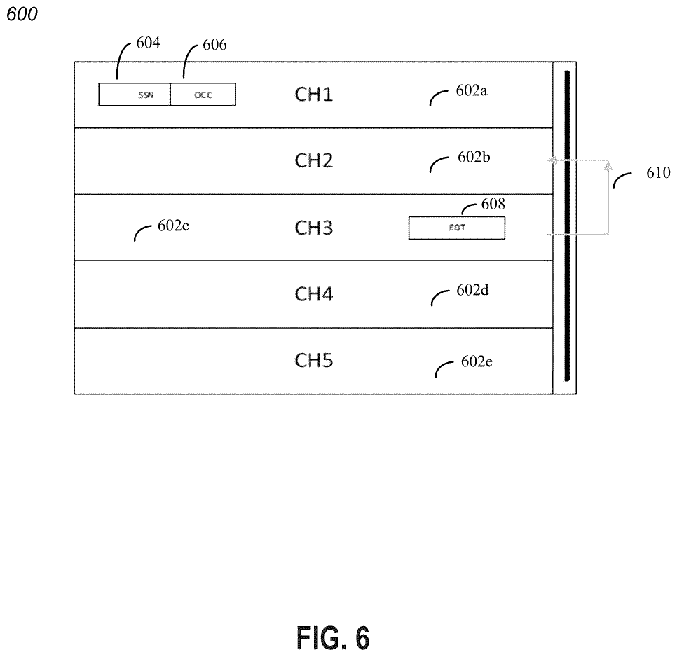

FIG. 6 illustrates an example implementation of a channel wrapper tile 600 incorporating embedded design-for-test (DFT) components for narrow channel architectures according to aspects described herein. The channel wrapper tile structure 600 accommodates multiple communication channels (602a-602e) while enabling efficient test signal routing through strategic component placement. This architecture supports complete transition to scan shift network (SSN) based operation without requiring SSN bypass mechanisms that traditionally limited implementation flexibility. The arrangement of components within the narrow channel structure demonstrates an optimized approach to test infrastructure implementation.

The channel wrapper tile 600 incorporates scan shift network (SSN) circuitry 604 and on-chip clock (OCC) circuitry 606 positioned within the uppermost channel 602a. This placement enables efficient clock distribution while maintaining signal integrity across the channel structure. The OCC circuitry 606 manages test clock generation and distribution while minimizing skew between channels 602a-602e. This arrangement supports synchronization across different clock domains while reducing routing complexity. According to certain aspects, the positioning of both SSN 604 and OCC 606 components within the same channel demonstrates an efficient use of available routing resources while maintaining optimal signal distribution paths throughout the structure.

An encoder/decoder for test (EDT) circuit 608 resides within the third channel 602c, and shows the capability of tile 600 to distribute test components across channel resources. A feedback path 610 connects the EDT circuit 608 to the second channel 602b. In some aspects, the feedback mechanism enables efficient test pattern application and response capture through localized signal paths. The strategic positioning of EDT circuit 608 and its associated feedback path 610 enables the channel wrapper tile 600 to function as a core-based DFT (CBDFT) structure while maintaining minimal routing overhead. The implementation supports various test modes through the coordinated operation of EDT circuit 608 and its feedback mechanism 610.

In some implementations, tile 600 can utilize routing schemes within the narrow channel limitations through placement of key components. The positioning of SSN circuitry 604 and OCC circuitry 606 in the uppermost channel 602a, combined with the centrally located EDT circuit 608 and its feedback path 610, creates an efficient test infrastructure that minimizes routing overhead while maintaining comprehensive test coverage. This arrangement allows test operations to proceed independently within each channel while preserving the ability to coordinate across channels as needed. The feedback path 610 plays a crucial role in enabling efficient test data circulation between channels 602b and 602c, optimizing the use of available routing resources.

In operation, test patterns can be efficiently distributed through the channel structure using the positioned components. The SSN circuitry 604 manages scan operations while the OCC circuitry 606 provides synchronized test clocks. The EDT circuit 608 processes test data, with its feedback path 610 enabling response capture and verification. The distributed, yet interconnected, arrangement supports various test modes while maintaining signal integrity across the channel structure.

The channel wrapper tile 600 can interface with broader test frameworks while maintaining its efficient internal structure. The arrangement of components within channels 602a-602e, particularly the SSN 604, OCC 606, and EDT 608 circuits, supports coordination with center hardware modules that manage system-level test functions. The feedback path 610 facilitates test data flow while maintaining the narrow channel structure.

The described architecture supports comprehensive test operations through its strategic component placement and interconnection scheme. The positioning of SSN 604 and OCC 606 in channel 602a, EDT 608 in channel 602c, and the implementation of feedback path 610 demonstrate how test resources can be efficiently distributed across available channels. The arrangement supports various operational modes while maintaining signal integrity and minimizing routing overhead. The feedback mechanism 610 enables efficient test pattern application and response capture, particularly between channels 602b and 602c.

This implementation of the channel wrapper tile architecture 600 showcases how strategic component placement and interconnection can optimize test operations within narrow channel constraints. The coordinated operation of SSN 604, OCC 606, EDT 608, and feedback path 610 enables comprehensive test coverage while minimizing routing overhead. The architecture's ability to support various test modes while maintaining signal integrity demonstrates its effectiveness for modern integrated circuit testing requirements. The feedback mechanism 610 plays a particularly important role in enabling efficient test data circulation, exemplifying the architecture's innovative approach to test resource utilization.

In one or more aspects, techniques for improving device operation may include additional aspects, such as any single aspect or any combination of aspects described below or in connection with one or more other processes or devices described elsewhere herein. In a first aspect, a device with improved operations may include an apparatus comprising a plurality of hardware modules (HMs) including a center HM, a bus interconnecting the plurality of HMs, and design-for-test (DFT) circuitry implemented in each HM. The HMs are configured to perform DFT operations for respective HMs through DFT circuitry comprising scan shift network (SSN) and encoder/decoder for test (EDT) circuits in each HM, with SSN multiplexing circuitry in the center HM managing SSN connections across the plurality of HMs. The apparatus is further configured to coordinate SSN operations across the plurality of HMs while executing independent DFT operations for each respective HM through standardized bus communication.

Additionally, the apparatus may perform or operate according to one or more aspects as described below. In some implementations, the apparatus includes an integrated circuit device, such as a system-on-chip (SoC) implementing the channel-less DFT architecture. In some implementations, the apparatus includes a semiconductor device having distributed test architecture components which enable efficient manufacturing test operations through localized DFT circuitry. In some implementations, the apparatus may include hardware test circuits and memory components coupled to test control logic. The hardware circuits may be configured to perform DFT operations described herein with respect to the apparatus. In some other implementations, the apparatus may include test controller circuits having configuration data recorded thereon, where the configuration data enables the test controller to perform operations described herein with reference to the apparatus. In some implementations, the apparatus may include one or more test interface components configured to perform operations described herein. In some implementations, a method of performing distributed DFT operations may include one or more operations described herein with reference to the apparatus.

In a first aspect, an apparatus implements a channel-less design-for-test (DFT) architecture, comprising: a plurality of hardware modules (HMs) including a center HM; a bus interconnecting the plurality of HMs configured for DFT data communication; and DFT circuitry implemented in each HM configured to perform DFT operations for a respective HM, wherein the DFT circuitry comprises a scan shift network (SSN) and an encoder/decoder for test (EDT) circuit in each HM, and SSN multiplexing circuitry in the center HM configured to manage SSN connections for the plurality of HMs.

In a second aspect, in combination with the first aspect, the SSN multiplexing circuitry is configured to coordinate SSN operations across the plurality of HMs, and the DFT circuitry in each HM is configured to execute DFT operations for a respective HM.

In a third aspect, in combination with one or more of the first aspect or the second aspect, each HM comprises: one or more input/output (I/O) ports; a first interface coupled to the I/O ports configured to receive a register-transfer level (RTL) description; and a second interface coupled to the I/O ports configured to receive a gate-level netlist, wherein the first and second interfaces enable the DFT circuitry to perform DFT operations based on at least one of the RTL description and the gate-level netlist.

In a fourth aspect, in combination with one or more of the first aspect through the third aspect, each HM further includes: a first module configured to manage I/O operations; and a second module configured to interface between different clock domains or voltage domains across other HMs.

In a fifth aspect, in combination with one or more of the first aspect through the fourth aspect, the DFT circuitry in the center HM further comprises on-chip clock (OCC) circuitry configured to transmit test clock signals to the plurality of HMs during DFT operations.

In a sixth aspect, in combination with one or more of the first aspect through the fifth aspect, the SSN is configured to process all scan operations in a respective HM, and the bus is configured to carry all inter-module DFT data.

In a seventh aspect, in combination with one or more of the first aspect through the sixth aspect, the SSN multiplexing circuitry in the center HM is configured to: receive scan data from an SSN in another HM via the bus; multiplex the received scan data; and transmit the multiplexed scan data to the SSN in the other HM via the bus.

In an eighth aspect, in combination with one or more of the first aspect through the seventh aspect, DFT operations performed by each HM are independent of DFT operations performed in other HMs.

In a ninth aspect, in combination with one or more of the first aspect through the eighth aspect, the bus is configured to carry all DFT signals between the plurality of HMs.

In a tenth aspect, in combination with one or more of the first aspect through the ninth aspect, the bus comprises a 32-bit bus.

In an eleventh aspect, in combination with one or more of the first aspect through the tenth aspect, at least one HM comprises a channel wrapper tile including: an EDT circuit and SSN circuit positioned in a channel of the channel wrapper tile; OCC circuitry positioned at an entry point of clock signals for the channel; and loopback circuitry configured to route DFT signals within the channel wrapper tile.

In a twelfth aspect, in combination with one or more of the first aspect through the eleventh aspect, the apparatus further comprises: an integrated Joint Test Action Group (JTAG) Debug Register (IJDR) circuit in each HM; and an IJDR host circuit in the center HM, wherein the IJDR circuit and IJDR host circuit are configured to enable a single JTAG interface for each HM.

In a thirteenth aspect, in combination with one or more of the first aspect through the twelfth aspect, each HM comprises: a DFT controller circuit configured to control an EDT circuit, an SSN circuit, OCC circuitry, and scan dump logic; and an IJDR and integrated Test Control Register (ITCR) coupled to the DFT controller circuit, wherein the IJDR and ITCR provide Test Access Port (TAP) and TCR controls for a respective HM.

In a fourteenth aspect, in combination with one or more of the first aspect through the thirteenth aspect, the apparatus performs a method comprising: communicating DFT data between the plurality of HMs via the bus; executing DFT operations at each of the plurality of HMs using the DFT circuitry comprising the SSN and EDT circuit; and managing SSN connections for the plurality of HMs using the SSN multiplexing circuitry in the center HM.

In a fifteenth aspect, in combination with one or more of the first aspect through the fourteenth aspect, the method further comprises: coordinating SSN operations across the plurality of HMs using the SSN multiplexing circuitry; and performing independent DFT operations at each of the plurality of HMs.

In a sixteenth aspect, in combination with one or more of the first aspect through the fifteenth aspect, the method further comprises: executing DFT operations in a channel wrapper tile having the EDT circuit and SSN circuit positioned in a channel, the OCC circuitry positioned at an entry point of clock signals for the channel, and the loopback circuitry routing DFT signals within the channel wrapper tile.

In a seventeenth aspect, in combination with one or more of the first aspect through the sixteenth aspect, the method further comprises: controlling DFT operations using the IJDR circuit in each of the plurality of HMs and the IJDR host circuit in the center HM; and enabling a single JTAG interface for each of the plurality of HMs.

In an eighteenth aspect, in combination with one or more of the first aspect through the seventeenth aspect, the method further comprises: receiving scan data from an SSN in one of the plurality of HMs via the bus; multiplexing the received scan data; and transmitting the multiplexed scan data to the SSN in the one of the plurality of HMs via the bus.

In a nineteenth aspect, in combination with one or more of the first aspect through the eighteenth aspect, the method further comprises: performing DFT operations in each of the plurality of HMs independently of DFT operations in other HMs; and communicating all DFT signals between the plurality of HMs exclusively via the bus.

In a twentieth aspect, in combination with one or more of the first aspect through the nineteenth aspect, the apparatus implements a distributed test architecture comprising a channel wrapper tile having multiple communication channels, wherein the channel wrapper tile comprises: an EDT circuit positioned in a center region; an SSN circuit positioned in the center region; OCC circuitry positioned at input interfaces of the channels; and a test communication bus coupled to the EDT and SSN circuits configured to communicate DFT data with other HMs.

In a twenty-first aspect, in combination with one or more of the first aspect through the twentieth aspect, the apparatus comprises hardware circuits configured to perform the method described in the fourteenth through nineteenth aspects.

In a twenty-second aspect, in combination with one or more of the first aspect through the twenty-first aspect, the apparatus comprises means for performing the method described in the fourteenth through nineteenth aspects.

In a twenty-third aspect, in combination with one or more of the first aspect through the twenty-second aspect, a hardware implementation comprises test circuitry configured to perform operations in accordance with any of the first through twentieth aspects.

In a twenty-fourth aspect, in combination with one or more of the first aspect through the twenty-third aspect, a system-on-chip (SoC) comprises test circuitry configured to perform operations in accordance with any of the first through twentieth aspects.

In a twenty-fifth aspect, in combination with one or more of the first aspect through the twenty-fourth aspect, an integrated circuit implementing the channel-less DFT architecture comprises: the plurality of HMs including the center HM; test communication circuitry; and DFT components configured to perform the operations described in any of the first through twentieth aspects.

In a twenty-sixth aspect, in combination with one or more of the first aspect through the twenty-fifth aspect, a semiconductor device implementing the distributed test architecture comprises: test control circuitry; communication interfaces; and hardware components configured to perform the operations described in any of the first through twentieth aspects.

In the figures, a single block may be described as performing a function or functions. The function or functions performed by that block may be performed in a single component or across multiple components, and/or may be performed using hardware, software, or a combination of hardware and software. To clearly illustrate this interchangeability of hardware and software, various illustrative components, blocks, modules, circuits, and steps are described below generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the example devices may include components other than those shown, including well-known components such as a processor, memory, and the like.

Unless specifically stated otherwise as apparent from the following discussions, it is appreciated that throughout the present application, discussions using terms such as “accessing,” “receiving,” “sending,” “using,” “selecting,” “determining,” “normalizing,” “multiplying,” “averaging,” “monitoring,” “comparing,” “applying,” “updating,” “measuring,” “deriving,” “settling,” “generating,” or the like, refer to the actions and processes of a computer system, or similar electronic computing device, that manipulates and transforms data represented as physical (electronic) quantities within the computer system's registers and memories into other data similarly represented as physical quantities within the computer system's registers, memories, or other such information storage, transmission, or display devices. The use of different terms referring to actions or processes of a computer system does not necessarily indicate different operations. For example, “determining” data may refer to “generating” data. As another example, “determining” data may refer to “retrieving” data.

The terms “device” and “apparatus” are not limited to one or a specific number of physical objects (such as one smartphone, one camera controller, one processing system, and so on). As used herein, a device may be any electronic device with one or more parts that may implement at least some portions of the disclosure. While the description and examples herein use the term “device” to describe various aspects of the disclosure, the term “device” is not limited to a specific configuration, type, or number of objects. As used herein, an apparatus may include a device or a portion of the device for performing the described operations.

Certain components in a device or apparatus described as “means for accessing,” “means for receiving,” “means for sending,” “means for using,” “means for selecting,” “means for determining,” “means for normalizing,” “means for multiplying,” or other similarly-named terms referring to one or more operations on data, such as image data, may refer to processing circuitry (e.g., application specific integrated circuits (ASICs), digital signal processors (DSP), graphics processing unit (GPU), central processing unit (CPU), computer vision processor (CVP), or neural signal processor (NSP)) configured to perform the recited function through hardware, software, or a combination of hardware configured by software.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Components, the functional blocks, and the modules described herein with respect to the Figures referenced above include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

Those of skill in the art that one or more blocks (or operations) described with reference to FIG. 2 may be combined with one or more blocks (or operations) described with reference to another of the figures. For example, one or more blocks (or operations) of FIG. 2 may be combined with one or more blocks (or operations) of FIG. 4 or FIG. 1. As another example, one or more blocks associated with FIG. 5 may be combined with one or more blocks (or operations) associated with FIGS. 1-3.

Those of skill in the art would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Skilled artisans will also readily recognize that the order or combination of components, methods, or interactions that are described herein are merely examples and that the components, methods, or interactions of the various aspects of the present disclosure may be combined or performed in ways other than those illustrated and described herein.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits, and processes described above. Whether such functionality is implemented in hardware or software depends upon the particular application and design constraints imposed on the overall system.

In one or more aspects, the operations described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

The operations of a method or algorithm disclosed herein may be implemented in a processor-executable software module which may reside on a computer-readable medium and commercially made available as a computer program product as software. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc wherein disks usually reproduce data magnetically and discs reproduce data optically with lasers. Combinations of the above should also be included within the scope of computer-readable media.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein but are to be accorded the widest scope consistent with this disclosure, the principles and the novel features disclosed herein.

Additionally, a person having ordinary skill in the art will readily appreciate, opposing terms such as “upper” and “lower,” or “front” and yack,” or “top” and “bottom,” or “forward” and “backward,” or “left” and “right” are sometimes used for ease of describing the figures, and indicate relative positions corresponding to the orientation of the figure on a properly oriented page, and may not reflect the proper orientation of any device as implemented.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown, or in sequential order, or that all illustrated operations be performed to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof.

The term “substantially” is defined as largely, but not necessarily wholly, what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

1. An apparatus implementing a channel-less design-for-test (DFT) architecture, the apparatus comprising:
a plurality of hardware modules (HMs), wherein the plurality of HMs includes a center HM;
a bus interconnecting the plurality of HMs configured for DFT data communication between the plurality of HMs; and
design-for-test (DFT) circuitry implemented in each of the plurality of HMs configured to perform DFT operations for a respective HM, wherein
DFT circuitry in each of the plurality of HMs comprises a scan shift network (SSN) and an encoder/decoder for test (EDT) circuit, and
DFT circuitry in the center HM further comprises SSN multiplexing circuitry configured to manage SSN connections for the plurality of HMs.

2. The apparatus of claim 1, wherein:
the SSN multiplexing circuitry is further configured to coordinate SSN operations across the plurality of HMs; and
the DFT circuitry in each of the plurality of HMs is configured to execute DFT operations for a respective HM.

3. The apparatus of claim 1, wherein each of the plurality of HMs comprises:
one or more input/output (I/O) ports;
a first interface coupled to the one or more I/O ports configured to receive a register-transfer level (RTL) description; and
a second interface coupled to the one or more I/O ports configured to receive a gate-level netlist,
wherein the first and second interfaces enable the DFT circuitry to perform DFT operations based on at least one of the RTL description and the gate-level netlist.

4. The apparatus of claim 1, wherein each of the plurality of HMs further includes:
a first module configured to manage input/output (I/O) operations; and
a second module configured to interface between different clock domains or voltage domains across other of the plurality of HMs.

5. The apparatus of claim 1, wherein the DFT circuitry in the center HM further comprises on-chip clock (OCC) circuitry configured to transmit test clock signals to the plurality of HMs during DFT operations.

6. The apparatus of claim 1, wherein
the SSN is configured to process all scan operations in a respective HM; and
the bus is configured to carry all inter-module DFT data.

7. The apparatus of claim 1, wherein the SSN multiplexing circuitry in the center HM is configured to:
receive scan data from a SSN in a other of the plurality of HMs via the bus;
multiplex the received scan data; and
transmit the multiplexed scan data to the SSN in the other of the plurality of HMs via the bus.

8. The apparatus of claim 1, wherein DFT operations performed by each of the plurality of HMs are independent of DFT operations performed in other HMs of the plurality of HMs.

9. The apparatus of claim 1, wherein the bus is configured to carry all DFT signals between the plurality of HMs.

10. The apparatus of claim 1, wherein the bus comprises a 32-bit bus.

11. The apparatus of claim 1, wherein at least one of the plurality of HMs comprises a channel wrapper tile, the channel wrapper tile comprising an embedded design-for-test (DFT) that includes:
an encoder/decoder for test (EDT) circuit and scan shift network (SSN) circuit positioned in a channel of the channel wrapper tile;
on-chip clock (OCC) circuitry positioned at an entry point of one or more clock signals for the channel; and
loopback circuitry configured to route one or more DFT signals within the channel wrapper tile.

12. The apparatus of claim 1, further comprising:
an integrated Joint Test Action Group (JTAG) Debug Register (IJDR) circuit in each of the plurality of HMs; and
an IJDR host circuit in the center HM,
wherein the IJDR circuit in each of the plurality of HMs and the IJDR host circuit in the center HM are configured to enable a single JTAG interface for each of the plurality of HMs.

13. The apparatus of claim 1, wherein each of the plurality of HMs comprises:
a DFT controller circuit configured to control:
an encoder/decoder for test (EDT) circuit,
a scan shift network (SSN) circuit,
on-chip clock (OCC) circuitry, and
scan dump logic; and
an integrated Joint Test Action Group (JTAG) Debug Register (IJDR) and integrated Test Control Register (ITCR) coupled to the DFT controller circuit, wherein the IJDR and ITCR provide Test Access Port (TAP) and Test Control Register (TCR) controls for a respective HM.

14. A method performed by an integrated circuit device, comprising:
communicating design-for-test (DFT) data between a plurality of hardware modules (HMs) via a bus, wherein the plurality of HMs includes a center HM;
executing DFT operations at each of the plurality of HMs using DFT circuitry comprising a scan shift network (SSN) and an encoder/decoder for test (EDT) circuit; and
managing SSN connections for the plurality of HMs using SSN multiplexing circuitry in the center HM.

15. The method of claim 14, further comprising:
coordinating SSN operations across the plurality of HMs using the SSN multiplexing circuitry; and
performing independent DFT operations at each of the plurality of HMs.

16. The method of claim 14, further comprising:
executing DFT operations in a channel wrapper tile, wherein the channel wrapper tile includes:
an EDT circuit and SSN circuit positioned in a channel of the channel wrapper tile;
on-chip clock (OCC) circuitry positioned at an entry point of one or more clock signals for the channel; and
loopback circuitry routing DFT signals within the channel wrapper tile.

17. The method of claim 14, further comprising:
controlling DFT operations using an integrated Joint Test Action Group (JTAG) Debug Register (IJDR) circuit in each of the plurality of HMs and an IJDR host circuit in the center HM; and
enabling a single JTAG interface for each of the plurality of HMs.

18. The method of claim 14, wherein managing SSN connections comprises:
receiving scan data from an SSN in one of the plurality of HMs via the bus;
multiplexing the received scan data; and
transmitting the multiplexed scan data to the SSN in the one of the plurality of HMs via the bus.

19. The method of claim 14, further comprising:
performing DFT operations in each of the plurality of HMs independently of DFT operations in other HMs; and
communicating all DFT signals between the plurality of HMs exclusively via the bus.

20. An apparatus implementing a distributed test architecture, the apparatus comprising:
a channel wrapper tile having a plurality of communication channels, the channel wrapper tile comprising:
an encoder/decoder for test (EDT) circuit positioned in a center region of the channel wrapper tile;
a scan shift network (SSN) circuit positioned in the center region of the channel wrapper tile;
on-chip clock (OCC) circuitry positioned at one or more input interfaces of the plurality of communication channels; and
a test communication bus coupled to the EDT circuit and the SSN circuit, the test communication bus configured to communicate design-for-test (DFT) data with other hardware modules.
